(19) United States
(12) Patent Application Publication
(10) Pub. No.: US 2026/0352195 A1
(43) Pub. Date: Nov. 5, 2026

(54) DIGITAL CIRCUITS AND METHOD TO ARBITRARILY INTERPOLATE PAM-N AND SQUARE WAVE SIGNALS

(71) Applicant: KEYSIGHT TECHNOLOGIES, INC., SANTA ROSA, CA (US)

(72) Inventors: Joseph Shaker, Colorado Springs, CO (US); Paul Holcomb, Colorado Springs, CO (US)

(21) Appl. No.: 19/296,368

(22) Filed: Aug. 11, 2025

Related U.S. Application Data
(60) Provisional application No. 63/797,692, filed on Apr. 30, 2025.

(51) Int. Cl. H03K 7/02; H03K 3/017

(52) U.S. Cl. CPC H03K 7/02; H03K 3/017

(57) ABSTRACT

A signal generation system is for generating a digital signal having a sequence of bit values. The system includes a multi modulus time accumulator configured to periodically generate, during each of successive unit periods of the digital signal, a time value indicative of a relative time within each unit period of the digital signal. The system further includes an edge computation subsystem configured to receive the time value and generate an edge blending value in accordance with the time value, and an output stage configured to control a transition between bit values of the signal in accordance with the blending value.

### CROSS-REFERENCE TO RELATED APPLICATION

A claim of priority is made to U.S. Provisional Patent Application No. 63/797,692, filed Apr. 30, 2025, in the U.S. Patent and Trademark Office, the disclosure of which is incorporated herein by reference in its entirety.

### FIELD

The present disclosure relates to digital signal processing circuits, and more particularly to circuits and methods for generating smoothly interpolated pulse-amplitude modulation (PAM) signals and square waves with arbitrary periods, transition lengths, and duty cycles.

### BACKGROUND

Arbitrary waveform generators (AWGs) are widely used in various fields such as telecommunications, signal processing, and electronic testing. These devices are capable of producing complex waveforms with precise control over frequency, amplitude, and phase characteristics. One common application of AWGs is the generation of pulse-amplitude modulation (PAM) signals and square waves, which are fundamental in digital communication systems and clock signal generation.

In digital communications, PAM-N signals represent data by modulating the amplitude of a series of signal pulses. The “N” in PAM-N denotes the number of distinct amplitude levels used to encode the data. For instance, PAM-2 is equivalent to binary signaling, while PAM-4 uses four amplitude levels to represent two bits per symbol. As data rates increase, there is a growing demand for AWGs capable of producing high-quality PAM-N signals with minimal distortion and precise timing.

Square waves, characterized by their rapid transitions between two voltage levels, are extensively used in digital systems as clock signals and in various testing applications. The ability to generate square waves with controllable frequency, duty cycle, and edge characteristics is valuable in many electronic design and testing scenarios.

However, generating high-quality PAM-N signals and square waves presents several challenges. One major issue is the occurrence of jitter, which refers to unwanted variations in the timing of signal transitions. Jitter can lead to increased bit error rates in communication systems and timing errors in digital circuits. Additionally, the transition edges of these signals often require careful shaping to control bandwidth and reduce electromagnetic interference.

Traditional methods for generating these signals often involve trade-offs between signal quality, flexibility, and hardware complexity. Simple digital-to-analog conversion techniques may produce signals with sharp transitions, leading to high-frequency components that can cause electromagnetic compatibility issues. On the other hand, more sophisticated approaches using complex filtering or oversampling techniques may require substantial computational resources or introduce unwanted artifacts.

Furthermore, many existing solutions struggle to provide fine control over signal characteristics such as transition time, edge shape, and timing precision across a wide range of frequencies. This limitation can be particularly problematic when generating low-frequency signals that require fast edge transitions or when precise control over the duty cycle is needed.

### SUMMARY

According to an aspect of the inventive concepts, a signal generation system for generating a digital signal having a sequence of bit values is provided. The system includes a multi modulus time accumulator configured to periodically generate, during each of successive unit periods of the digital signal, a time value indicative of a relative time within each unit period of the digital signal. The system further includes an edge computation subsystem configured to receive the time value and generate an edge blending value in accordance with the time value, and an output stage configured to control a transition between bit values of the signal in accordance with the blending value.

The output stage may be configured to combine a previous bit value and a current bit value based on the edge blending value.

The multi modulus time accumulator may include a coarse accumulator configured to generate a coarse time value, and a fine accumulator configured to generate a fine time value. The coarse accumulator may be N bits long and store a fixed point number in a range of [0, 1) with granularity of 1/(2\hat{ }N). The fine accumulator may have a programmable modulus and store a number in a range of [0, FineModulus). Increments of the coarse and fine accumulators may be programmable, and overflows of the fine accumulator may cause an increment of the coarse accumulator.

The edge computation subsystem may include a lookup table storing pre-computed edge shape values for each of the time values (the time values each being a fixed-point number between 0 and 1), and an interpolator configured to interpolate between stored edge shape values based on the time value. The lookup table may store values corresponding to the step response of an arbitrary low pass filter.

The system may further include a programmable edge duration input, wherein the edge computation subsystem is configured to generate the edge blending value based on the time value and the programmable edge duration input.

The edge computation subsystem may include an edge duration comparison module configured to compare the time value to a programmable edge duration threshold, an edge rescaling module configured to rescale those time values representing the edge duration from [0, edge_duration) to [0, 1) based on the comparison, and a lookup table configured to store edge shape values for the rescaled time values. The edge computation subsystem may further include interpolation logic configured to interpolate between the edge shape values based on the rescaled time value. The lookup table may store piecewise linear representations of the step response of an arbitrary low pass filter.

The output stage may be configured to generate a pulse-amplitude modulation (PAM) signal having N levels, where N is an integer greater than or equal to 2. N may be greater than 2.

The system may further include a comparison circuit configured to compare a duty cycle input to the time value, a subtractor configured to subtract the duty cycle input from the time value, and a multiplexer configured to output either the time signal or an output of the comparison circuit under control of an output of the comparison circuit. Here, the edge computation subsystem is configured to receive the output of the multiplexer and generate an edge blending value in accordance with the output of the multiplexer, and the output stage is configured to control the transition between bit values of the digital signal in accordance with output of the comparison circuit and the blending value. In this case, the digital signal is a square wave signal, and the duty cycle of the square wave signal is programmable.

According to another aspect of the inventive concepts, a method for generating a digital signal with controlled edge transitions is provided. The method includes generating a time value using a multi modulus time accumulator, computing an edge blending factor based on the time value, and combining a current sample and a previous sample using the edge blending factor to produce a transition-smoothened output signal.

Generating the time value may include generating a fine time value using a fine accumulator, and generating a coarse time value using a coarse accumulator. The coarse time value may be generated as a fixed-point number in a range of [0, 1).

Computing the edge blending factor may include comparing the time value to an edge duration threshold, rescaling the time value based on the comparison, accessing a lookup table storing edge shape values, and interpolating between the edge shape values based on the rescaled time value. Here, the lookup table may store piecewise linear representations of an arbitrary curve.

### BRIEF DESCRIPTION OF THE DRAWINGS

The above and other aspects and features of the inventive concepts will become readily apparent from the detailed description that follows, with reference to the accompanying drawings, in which:

FIG. 1 is a circuit diagram for reference in describing the generation of smooth interpolations between PAM-N waveforms according to an embodiment of the inventive concepts;

FIG. 2 is a circuit diagram for reference in describing the generation of smoothened square waves of an arbitrary duty cycle according to another embodiment of the inventive concepts;

FIG. 3 is a graph for reference in describing lookup table (LUT) implementation of different transfer functions according to embodiments of the inventive concepts;

FIG. 4 is a graph for reference in describing rescaling of a sampled edge over time according to embodiments of the inventive concepts;

FIG. 5 is a graph for reference in describing the frequency response of square waves with different edge shapes according to embodiments of the inventive concepts; and

FIG. 6 is a graph for reference in describing the frequency response of a same edge shape with different durations according to embodiments of the inventive concepts.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

The drawings may in some cases focus on structural features of embodiments of the inventive concepts. However, the drawings may not be drawn to scale, and relative dimensions of different structural elements may differ from those depicted in the drawings. Further, throughout the drawings, like reference numbers refer to the same or similar elements.

As is traditional in the field of the inventive concepts, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

One common type of signal that an Arbitrary Waveform Generator (AWG) produces is a 2-level (NRZ) or N-level (PAM-N) signal, where the signal has a steady value for one bit time before transitioning to another value for the next bit time. These are often used for communication, as the data signal or as the clock signal. It is often desirable for the edges (the transition between the steady-state bit values) to have particular user-specified characteristics, for example to have a given 10%-90% rise-time or fall-time, or to be bandwidth-limited, or to be Gaussian-shaped. Often the behavior of the edge portion of the waveform impacts the behavior of the level portion, causing overshoot, undershoot, or ringing. Gaussian-shaped edges have the fastest rise time with no overshoot possible for a given amount of bandwidth.

AWGs usually operate by sending a sequence of voltage samples to a digital-to-analogy converter (DAC) running at a fixed output sample rate. This rate is usually unrelated to the data rate of the target waveform, so there needs to be a method for transforming the waveform information into the fixed-rate samples at the DAC, while preserving the important edge and level characteristics of the waveform.

Naively sending square waves out as 1-bit signals have 2 main issues. First, they have a lot of aliasing, leading to jitter. Second, they often times cause a lot of ringing. As will be explained later, the inventive concepts present ways to mitigate both of these by generating waveforms with controlled high frequency rolloff. The inventive concepts enable generation of arbitrary frequency/period waveforms with smooth and programmable (and decoupled from the period) edge transitions at low hardware complexity.

In prior solutions, a general AWG algorithm is used to represent the data signal using 1 (or exactly N) samples per unit interval and then a programmable-ratio re-sampler is used to transform the data samples into the DAC samples. This works, but often involves a high interpolation ratio (e.g., 1 sample per bit on a square wave at 1 MHz sent to a 1 GHz DAC requires a ratio of 1000, and 1 sample on the original square wave is not enough to accurately represent the edge shape). High interpolation rates oftentimes require introducing ringing (usually with sin x/x interpolation) and/or extremely slow edges (usually with linear interpolation)—neither of which is desirable.

In an alternative solution, a comparator (in the digital domain) can be used after the re-sampler to sharpen the edges. This works (especially when it follows a high-quality NCO generating sine waves at precise frequencies), but a naïve implementation will transition from level 0 to level 1 in one sample time (as fast as possible). A more complex implementation of the comparator can use linear interpolation to estimate the exact threshold crossing time for the transition. However, this loses information in the quantization to a log(N)-bit waveform or in the process of quantizing to exactly level-0 or level-1 values (nothing in between). This then introduces lots of harmonics (which alias) and the smooth, bandlimited transition is lost. The aliases cause jitter in the edge locations relative to their true locations. It is non-trivial to implement a smooth comparator which preserves exact positions of edge locations (even inter-sample), while maintaining a fast transition time over a very wide range of output bit periods.

In still another solution, floating-point math is used to evaluate something like a tanh function based on the estimated crossing time to compute what the smooth resampled outputs should be. This is easier to do in non-real-time contexts where one can afford to spend more processing power on computing exactly when the crossing time should be and evaluating some smooth function to produce the waveform level in the neighborhood of the crossing.

Yet another solution is to compute ahead of time and store multiple oversampled versions of the waveform, each oversampled by different amounts. Say we have a DAC at some sample rate Fs and store a 10 pt waveform. That waveform can be played with a max repetition speed of Fs/10, and can contain up to the 5^{th} harmonic before exceeding Nyquist. Instead, let's store another version of that waveform that's 20 pts instead. That waveform can only be played with maximum repetition speed of Fs/20 (slower), but it can contain up to the 10^{th} harmonic before exceeding Nyquist. So, it can have more detail at the edges and other features.

And lastly, another solution is to generate a square wave directly using the Fourier Series as a sum-of-sines. This is generally speaking impractical to do in hardware, especially for low frequency waveforms relative to the sample rate as these may need to be made as the sum of hundreds of thousands of sines to have good rise-time properties.

Contrary to prior solutions, the inventive concepts offer a relatively low-cost circuit that can produce arbitrary, smooth edges and arbitrary UI (unit interval) periods. Even when using a slow UI period the circuit can maintain fast edges. For example, in one implementation we can produce a smooth 10 ns rise-time Gaussian-shaped edge on a 10 milli-Hz square wave.

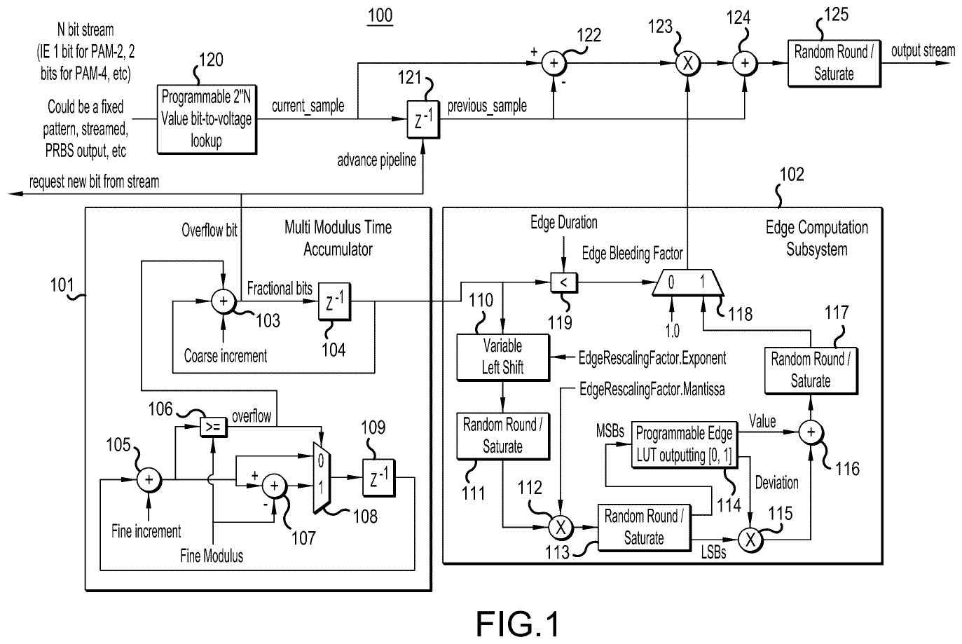

FIG. 1 is a circuit diagram for reference in describing the generation of smooth interpolations between PAM-N waveforms according to an embodiment of the inventive concepts. Here, N is a positive integer. In some embodiments, N is a power of 2 (i.e., 2, 4, 8 . . . ).

Referring to FIG. 1, the illustrated circuit 100 includes a Multi Modulus Time Accumulator (MMTA) 101 and an Edge Computation Subsystem 102. The remaining circuitry appearing at the top of FIG. 1 may be referred to as an output stage. Briefly, MMTA 101 is configured to periodically generate, during each of successive unit periods of the generated digital signal, a time value indicative of a relative time within each unit period of the digital signal. The Edge Computation Subsystem 102 is configured to receive the time value and generate an edge blending value in accordance with the time value. The output stage is configured to control a transition between bit values of the signal in accordance with the blending value. In some examples, the output stage is configured to combine a previous bit value and a current bit value based on the edge blending value.

The MMTA 101 controls the frequency of the data waveform relative to the output sample rate fs. In the example of FIG. 1, the MMTA 101 is made of a cascade of two accumulators, a coarse accumulator 102a and a fine accumulator 102b

The coarse accumulator 102a of example embodiments is N bits long and stores a fixed point number in range [0, 1) with granularity of 1/(2**N). When the coarse accumulator 102a overflows, a new sample is pulled. The coarse accumulator alone allows one to represent frequencies of the form f=X/(2**N)fs.

In the specific example of FIG. 1, the coarse accumulator includes an adder 103 and a unit delay Z⁻¹ 104. As shown, the adder 103 combines a value received from the fine accumulator 102b with an output of the unit delay Z⁻¹ 104 and a programmable coarse increment. Fractional bits output by the adder 103 form the time value mentioned above, whereas an overflow bit from the adder 103 is applied to the output stage.

To be able to represent more frequencies, the fine accumulator 102b is provided which is of a programmable modulus and stores a number in range [0, FineModulus).

In example embodiments, when the fine accumulator 102b overflows, 1/(2**N) is added to the Coarse Accumulator 102a. This allows representation of other, non-integer power of two denominators. In particular, frequencies can be represented in decimal precision (XXX.YYY MHz, for many decimal digits of frequency), limited by the largest power of 5 that can be fixed in the fine accumulator 102b (5=10/2 is the part of powers of 10 that cannot be represented exactly by the binary coarse accumulator 102a).

The time value output from the MMTA 101 is then sent to the Edge Computation Subsystem 102. This subsystem produces a number edge blending in [0, 1]. This number is used in the edge portions of the waveform (where it is transitioning from the previous sample level to the current sample level). In example embodiments, edge blending is used as a weight in the following linear combination equation:

output=edge_blending*(current_sample−previous_sample)+previous sample=edge_blending*current_sample+(1−edge_blending)*previous_sample

In the example of FIG. 1, a comparator 119 determines if the MMTA 101 generated time value is greater than a programmable edge duration (EdgeDuration). If yes, the comparator 119 controls a multiplexer (MUX) 118 to simply output 1 because the waveform is in the steady-state level portion rather than the edge portion. Otherwise (i.e., for the edge portions) the time value is rescaled from the range [0, EdgeDuration) to the range [0, 1). In the current sample embodiment, this is achieved by multiplying it by EdgeRescalingFactor (which should equal 1/EdgeDuration), which may be implemented as in FIG. 1 with an Exponent controlling a variable left shift unit 110 and a Mantissa applied to a fixed-point multiplier 113 together with the output of a random round/saturate unit 111.

Now that a value in [0, 1) has been obtained, the process continues to compute the smoothened edge using some kind of algorithmic process. In some cases, a polynomial may be evaluated directly. For example, the cubic Smoothstep curve may be used to produce a smooth transition.

Alternatively, as in FIG. 1, a lookup table may be used to interpolate between stored points of a more complex edge shape. The lookup table 114 may take the most significant bits (MSBs) of the [0, 1) time-in-edge value (from the random round/saturate unit 113) to select a programmable Value/Derivative pair. The least significant bits (LSBs) may then be used to interpolate between table entries using a multiplier 115. The Value and interpolation are summed by an adder 116, with the result applied to the random round/saturate unit 117 and output as the edge factor via the MUX 118 to the output stage illustrated at the top of FIG. 1.

The output stage of the illustrated example includes programmable 2**N value bit-voltage lookup unit 120 receiving an N bit stream and outputting a sequence of current samples. For example, the N bit stream is 1 bit for PAM-2, 2 bits for PAM-4, and so on. The stream may be a fixed pattern, streamed, PRBS output, and so on.

The current sample is stored in a unit memory Z⁻¹ 121 at a timing controlled by the overflow bit from the MMTA 101 discussed previously. The overflow bit is also used to request a next bit from the stream.

An adder 122 of this example subtracts a previous sample output by the unit memory Z⁻¹ 121 from the current sample, and the result is multiplied by the Edge Blending Factor using a multiplier 123. The resultant product is added to the previous sample to obtain the final output stream having the smoothened edge shape (after passing through another random round/saturate unit 125).

As described above, according to the embodiment of FIG. 1, edge blending is used to combine the previous and current samples to produce the output samples. A new output sample is produced every clock, using the newly computed edge_blending, (and new samples, if the CoarseAccumulator overflowed). Here the UI period is 1/(fs*CoarseIncrement) and transition time is EdgeDuration/(fs*CoarseIncrement).

Frequency modulation on the output waveform can be generated by adding a time-varying waveform to CoarseIncrement before the accumulator. This can be done to, among other things, model Spread Spectrum Clocking (SCC). Phase modulation can be generated by adding a time-varying waveform to the output of the MMTA before the Duty Cycle/Edge computation circuit. This can be done to, among other things, model phase noise.

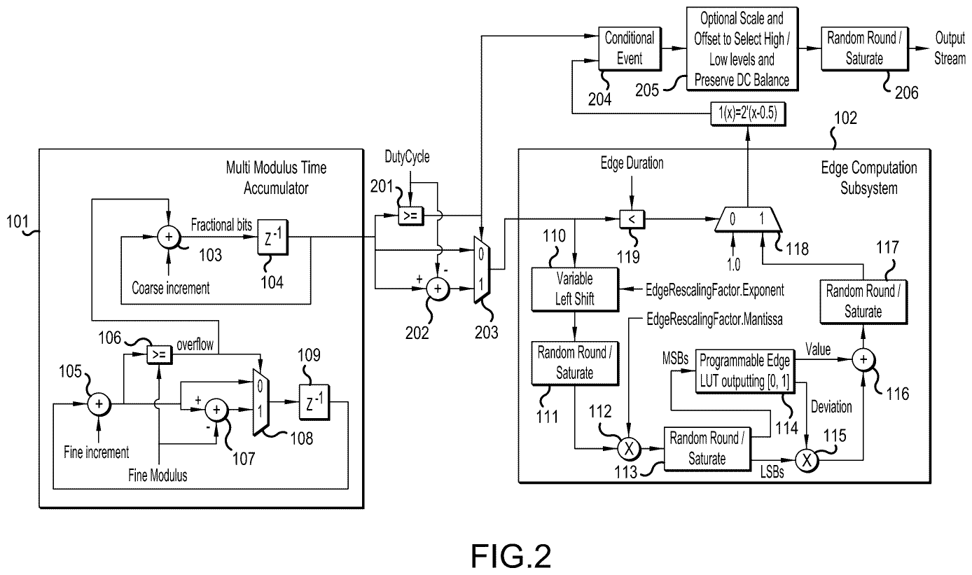

FIG. 2 illustrates an alternative embodiment of a system for generating smoothened square waves according to an embodiment of the inventive concepts.

Referring to FIG. 2, the MMTA 101 and the Edge Computation Subsystem 102 may be configured in and operated similarly to the MMTA 101 and Edge Computation Subsystem 102 discussed above in connection with FIG. 1. Accordingly, a detailed description of the MMTA 101 and the Edge Computation Subsystem 102 of FIG. 2 is omitted here to avoid redundancy in the description.

Consider that a square wave has the following time bounds of each waveform:

| Time Bounds | Behavior of Waveform |
|---|---|
| [0, EdgeDuration) | Rising Edge |
| [EdgeDuration, DutyCycle) | Steady State High |
| [DutyCycle, DutyCycle + EdgeDuration) | Falling Edge |
| [DutyCycle + EdgeDuration, 1) | Steady State Low |

The circuit of the embodiment of FIG. 2 utilizes a comparator 201 to compare the current time accumulator value to the DutyCycle. If the current time accumulator value is before the DutyCycle, the output of the comparator 201 controls a MUX 203 to output 0 to the Edge Computation Subsystem 102.

On the other hand, and the current time accumulator value is at or past the DutyCycle, the comparator 201 controls a MUX 203 to output the difference (obtained by an adder 202) between the accumulator value and the DutyCycle to the Edge Computation Subsystem 102. The Edge Computation Subsystem 102 calculates the edge blending factor for the edge in range [0, EdgeDuration) which is used to produce an output level. Namely, the edge blending factor (f(x)) conditionally inverted by unit 204 according to the output from the comparator 201, and a unit 205 produces the output level to optimal scale and offset, and selected high/low levels to preserve DC balance. The resultant is passed through a random round/saturate unit 206 and output as the final output stream.

In both embodiments described above, the edge shape may be arbitrary, but in some cases, it may be an S-shaped curve to minimize value and higher-order derivative discontinuities at the edges. Various mathematical functions may be used to achieve different edge shapes:
1. Logistic curve: In some cases, the function f(x)=1/(1+e\hat{ }−x) may be used in the lookup table to produce a smooth, S-shaped transition.
2. Error function (Erf): The EdgeComputationSubsystem may store the Erf function, which represents the convolution of a Gaussian function with a step function. This may be stored within a reasonable number of standard deviations, such as ±4 standard deviations.
3. Step response of an arbitrary function: In some cases, the step response of an arbitrary low pass filter (perhaps a windowed sinc) may be stored in the lookup table. This may give a faster rise time and reduced passband rolloff compared to the Erf function, at the cost of some overshoot and undershoot—which also results in the table needing to store values outside of [0, 1)

The Edge Computation Subsystem 102 may effectively store an extremely oversampled step response and downsample it appropriately. By varying the EdgeTime relative to the output sample rate, the width of the applied lowpass filter may be effectively varied. This process may move the transition band or stop band position of the filter, where a fast edge shrinks the filter, increasing its stopband frequency, and a slow edge widens the filter, decreasing its stopband frequency.

In some cases, the Edge Computation Subsystem 102 may be configured to ensure that the EdgeTime is slow enough to provide sufficient stopband attenuation by Nyquist, preventing aliasing back into the passband as a result of undersampling. The specific configuration may depend on the desired tradeoff between edge speed and aliasing prevention.

By taking a sharp discontinuity (a step function) and convolving it with some (finite duration) lowpass filter and storing the result of that convolution in a precomputed lookup table (stored very densely, so one can get time offsets from the convolution), one can obtain a more-or-less bandlimited step function which can be used to piece together the desired waveform from the steady-state levels of the data function and this bandlimited step for the edges. This combined waveform is sufficiently bandlimited waveform such that there is minimal harmonic content above the Nyquist frequency that folds back into our passband, therefore eliminating jitter and uncertainty in transition times.

Consider the following example calculation: how much is “enough stopband attenuation” and how fast of an edge can we produce?

Suppose that we store in our LUT±4 standard deviations of a Gaussian filter. If one were to program EdgeTime to be 9 output samples, then there would be one output sample per time domain standard deviation (9=center±4 samples). The Fourier Transform of a Gaussian is a Gaussian and the product of their standard deviations is a constant: (sigma_f)(sigma_t)=½*pi. Using this one can calculate that a standard deviation of 1 sample in time domain corresponds to a standard deviation in the frequency domain of fs/2*pi. The rolloff of a Gaussian at n standard deviations away, in decibels, is 20*log 10(e\hat{ }−((n\hat{ }2)/2)). Nyquist is 0.5 fs, or pi frequency domain standard deviations, so one will have a rolloff of about 42 dB at Nyquist.

By contrast, if we program EdgeTime to be 4 output samples, then our time domain standard deviation becomes 0.444 samples (4/9), so the frequency domain standard deviation is 2.25*fs/2*pi, so Nyquist is at pi/2.25 frequency standard deviations, giving a rolloff of about 8.47 dB at Nyquist. This is probably small enough that one would see substantial aliasing.

At the same time, note that a square wave's harmonics do slowly roll off over frequency so we would be applying this attenuation to some higher harmonic that's already somewhat rolled-off—so in the latter case the aliases would be at lower than −8 dB.

One might choose to allow aliasing back to 0.4 Fs, if the bandwidth of interest of their system only extends to 40% of Fs (or if they have a bandlimiting filter downstream), in that case the critical rolloff of interest would be the rolloff at 0.6 Fs, rather than the rolloff at 0.5 Fs. Similar computations can be done for other filter kernels.

Here one may implement the restriction that EdgeTime<1 UI period to avoid having to do more complex calculations of overlapping time shifted step responses—doing so is possible but would need more hardware. This means that at faster UI periods one is limited as to how long the filter can be and therefore how low of a cutoff frequency and how much aliasing protection can be obtained (although—if the filter is longer than 1 UI period, one would have some ISI anyway). Note also here that one is storing a truncated Gaussian, one that only extends to +/−4 standard deviations in the LUT. If we expand out the table to store, say, +/−10 standard deviations, then a more accurate step response is obtained—but this increases the minimum UI period to get the same amount of filtering as one will now need a longer EdgeTime to get the same cutoff frequency. There is a tradeoff in filter length and minimum UI period.

If one wants to get a filter response that spans many UI, it may be desirable to produce an oversampled result to make sure there is no aliasing at that higher sample rate and are jitter free and then use a polyphase decimation filter by a fixed amount to bandlimit, smear, and reduce sample rate. That decimated result should also be jitter free if the downsampling filter is of sufficient quality, though it will likely cause ringing and ISI.

One can fairly easily generate N samples per clock cycle (which may be desired, especially in the case of oversampling and then decimating) by, for each output sample i in [0, N), outputting a sample at value CoarseAccumulator+i*CoarseIncrement N. For power-of-2 values of N, the divide by N is trivial. One is essentially interpolating the time accumulator between samples of the clock. For the square wave circuit of FIG. 2, this is all that needs to be done. For the resampler circuit, some more work may be needed to handle cases where there is an overflow to the next input sample mid clock cycle on one of the intermediate samples—though this is easy enough to solve by extending the length of the internal buffer of the resampler and possibly requiring the upstream circuit to generate multiple samples per request.

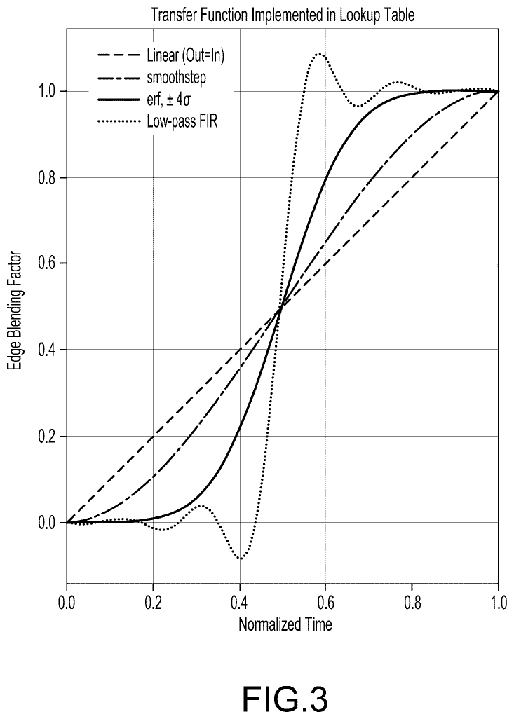

FIG. 3 is a graph for reference in describing lookup table (LUT) implementation of different transfer functions according to embodiments of the inventive concepts. In particular, this figure shows various functions one could store in the LUT in the edge computation system, which each map a [0, 1) time input to a [0, 1) blending value. Note that if a generic low pass filter is used, the output may have ringing and actually exceed the range [0, 1) slightly.

For simpler functions (especially linear, and possibly smooth step), hardware can do direct evaluation whereas for more complicated functions hardware likely needs to use a LUT.

The edge shape chosen usually has odd symmetry about the 0.5 point. This enables practical implementations to reduce the lookup table size by a factor of 2 at the cost of some minor additional processing.

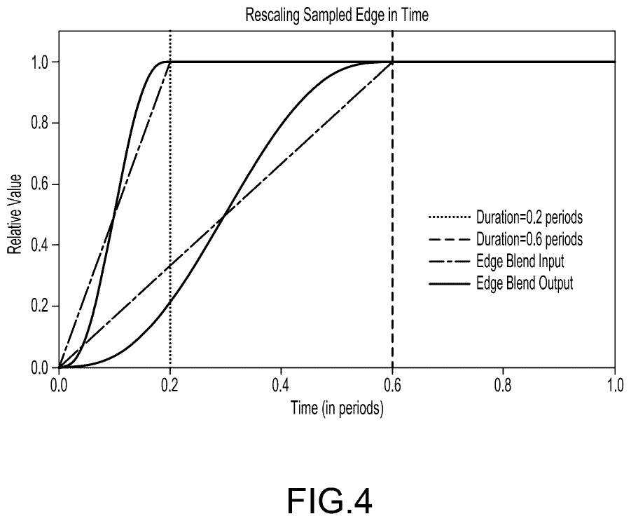

FIG. 4 is a graph for reference in describing rescaling of a sampled edge over time according to embodiments of the inventive concepts. In particular, this figure shows how by reprogramming the EdgeDuration and EdgeRescalingFactor we get a different input to the edge blender (which may use the LUT discussed above) and therefore a different edge shape. This essentially lets us stretch or compress our edge duration as a fraction of 0 to 1 UI periods, allowing semi independent control of UI period and edge length—though there is a limitation that this invention does not allow for an edge length>1 UI period.

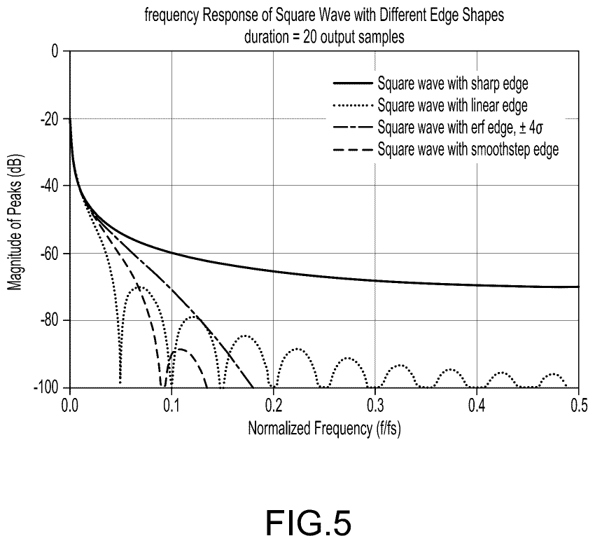

FIG. 5 is a graph for reference in describing the frequency response of square waves with different edge shapes according to embodiments of the inventive concepts. That is, this figure shows how various edge types have different kinds of frequency roll off. With just a purely sharp edge, the roll off is slow and the high-frequency components cause artifacts when they alias back in-band as we sample the edge for the output waveform. This causes noticeable jitter and other artifacts in the output. With these other edge types, you can get a much quicker roll off, making the edge essentially bandlimited and safe to sample in a bandlimited manner.

Notice of the 3 shapings shown how linear shaping has the narrowest main lobe (that is the fastest initial roll off) but has the worst stop band attenuation, while Erf shaping with a width of 4A stored in the table has the widest main lobe but the best stopband attenuation. The narrower main lobe might allow for a shorter minimum number of output samples per UI period, for decent performance, but at more samples per UI will never achieve performance as good as the Erf Smoothstep fits somewhere in the middle. One could also store an Erf sampled over a narrower range of a to reduce the main lobe width but also decrease the stopband attenuation. Clearly more exploration could be done with different smoothening shapes while maintaining the core ideas of the inventive concepts.

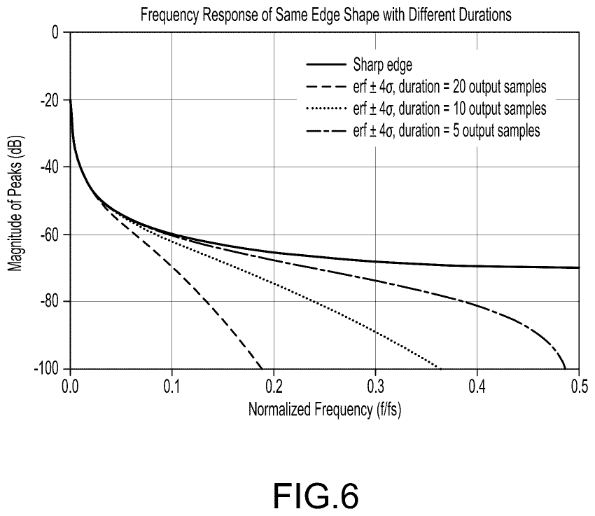

FIG. 6 is a graph for reference in describing the frequency response of a same edge shape with different durations according to embodiments of the inventive concepts. That is, this figure shows how harmonic content changes as a function of the edge duration. Making the edge duration longer (spread out over more output samples) makes the edge narrower in the frequency domain and therefore reduces the bandwidth of the edge and eliminates aliasing—which is the cause of jitter in these systems.

This is shown with the Erf edge type with ±4σ stored in the lookup table. The other edge types show similar behavior. We observe that edge durations shorter than about 5 samples with this edge type do not give enough stopband attenuation to sufficiently squash jitter. This 5 (or N) sample minimum (which is a function of what is stored in the lookup table) sets the minimum viable UI period, since the current embodiments limit edge durations to be less than or equal to the UI period.

While the disclosure has been particularly illustrated and described with reference to exemplary embodiments thereof, it will be appreciated by those of ordinary skill in the art that changes may be made therein without departing from the principles and spirit of the disclosure, the scope of which is defined in the appended claims and their equivalents. The exemplary embodiments should be considered in a descriptive sense only and not for purposes of limitation. Therefore, the scope of the disclosure is defined not by the detailed description of the disclosure but by the appended claims, and all differences within the scope will be construed as being included in the disclosure.

What is claimed is:

1. A signal generation system for generating a digital signal having a sequence of bit values, comprising:
a multi modulus time accumulator configured to periodically generate, during each of successive unit periods of the digital signal, a time value indicative of a relative time within each unit period of the digital signal;
an edge computation subsystem configured to receive the time value and generate an edge blending value in accordance with the time value; and
an output stage configured to control a transition between bit values of the signal in accordance with the blending value.

2. The signal generation system according to claim 1, wherein the output stage is configured to combine a previous bit value and a current bit value based on the edge blending value.

3. The signal generation system of claim 1, wherein the multi modulus time accumulator comprises:
a coarse accumulator configured to generate a coarse time value; and
a fine accumulator configured to generate a fine time value.

4. The signal generation system of claim 3, wherein the coarse accumulator is N bits long and stores a fixed point number in a range of [0, 1) with granularity of 1/(2\hat{ }N).

5. The signal generation system of claim 4, wherein the fine accumulator has a programmable modulus and stores a number in a range of [0, FineModulus),
wherein increments of the coarse and fine accumulators are programmable, and
wherein overflows of the fine accumulator cause an increment of the coarse accumulator.

6. The signal generation system of claim 1, wherein the edge computation subsystem comprises:
a lookup table storing pre-computed edge shape values for each of the time values, the time values each being a fixed-point number between 0 and 1; and
an interpolator configured to interpolate between stored edge shape values based on the time value.

7. The signal generation system of claim 6, wherein the lookup table stores values corresponding to the step response of an arbitrary low pass filter.

8. The signal generation system of claim 1, further comprising a programmable edge duration input, wherein the edge computation subsystem is configured to generate the edge blending value based on the time value and the programmable edge duration input.

9. The signal generation system of claim 1, wherein the edge computation subsystem comprises:
an edge duration comparison module configured to compare the time value [0, edge_duration) to a programmable edge duration threshold;
an edge rescaling module configured to rescale the time value to [0, 1) based on the comparison; and
a lookup table configured to store edge shape values for the rescaled time values.

10. The signal generation system of claim 9, wherein the edge computation subsystem further comprises:
interpolation logic configured to interpolate between the edge shape values based on the rescaled time value.

11. The signal generation system of claim 9, wherein the lookup table stores piecewise linear representations of the step response of an arbitrary low pass filter.

12. The signal generation system of claim 1, wherein the output stage is configured to generate a pulse-amplitude modulation (PAM) signal having N levels, where N is an integer greater than or equal to 2.

13. The signal generation system of claim 12, wherein N is greater than 2.

14. The signal generation system of claim 1, further comprising:
a comparison circuit configured to compare a duty cycle input to the time value;
a subtractor configured to subtract the duty cycle input from the time value; and
a multiplexer configured to output either the time signal or an output of the comparison circuit under control of an output of the comparison circuit,
wherein the edge computation subsystem is configured to receive the output of the multiplexer and generate an edge blending value in accordance with the output of the multiplexer, and
wherein the output stage is configured to control the transition between bit values of the digital signal in accordance with output of the comparison circuit and the blending value.

15. The signal generation circuit of claim 14, wherein the digital signal is a square wave signal, and a duty cycle of the square wave signal is programmable.

16. A method for generating a digital signal with controlled edge transitions, comprising:
generating a time value using a multi modulus time accumulator;
computing an edge blending factor based on the time value; and
combining a current sample and a previous sample using the edge blending factor to produce a transition-smoothened output signal.

17. The method of claim 16, wherein generating the time value comprises:
generating a fine time value using a fine accumulator; and
generating a coarse time value using a coarse accumulator.

18. The method of claim 17, wherein the coarse time value is generated as a fixed-point number in a range of [0, 1).

19. The method of claim 16, wherein computing the edge blending factor comprises:
comparing the time value to an edge duration threshold;
rescaling the time value based on the comparison;
accessing a lookup table storing edge shape values; and
interpolating between the edge shape values based on the rescaled time value,
wherein the lookup table stores piecewise linear representations of an arbitrary curve.

20. The method of claim 16, wherein the smoothened output signal is a pulse-amplitude modulation (PAM) signal having N levels, where N is an integer greater than or equal to 2.
